(19) United States
(12) Patent Application Publication
(10) Pub. No.: US 2021/0089404 A1
(43) Pub. Date: Mar. 25, 2021

(54) MEMORY POWER TERMINATION DELAYS

(71) Applicant: Hewlett-Packard Development Company, L.P., Spring, TX (US)

(72) Inventors: Monji G. Jabori, Spring, TX (US); Byron A. Alcorn, Fort Collins, CO (US); Jonathan Vu, Spring, TX (US)

(73) Assignee: Hewlett-Packard Development Company, L.P., Spring, TX (US)

(21) Appl. No.: 16/980,880

(22) PCT Filed: Jun. 11, 2018
(86) PCT No.: PCT/US2018/036866

§ 371 Date: Sep. 15, 2020

(51) Int. Cl. G06F 11/14; G11C 5/14; G06F 1/3203

(52) U.S. Cl. CPC G06F 11/1441; G06F 1/3203; G11C 5/148

(57) ABSTRACT

Example implementations relate to memory power termination delays. In some examples, a computing system may include a memory storage device, a memory controller, an input/output (I/O) controller, a power management controller (PMC), a bus compliant with an Enhanced Serial Peripheral Interface (eSPI) protocol, and a power control gating. The input/output controller may transmit a power termination command to the power management controller via the bus compliant with the eSPI protocol. Upon a receipt of the power termination command, the PMC may initiate a delay period of an assertion of the power termination command to the power control gating and transmit a memory transfer command to the memory controller included in the memory storage device. The memory controller, upon receipt of the memory transfer command, may move data stored in volatile memory to non-volatile memory included in the memory storage device. Upon expiration of the delay period, the PMC may assert the power termination command to the power control gating to remove power from the computing system.

### BACKGROUND

Data from a computing system may be stored in volatile memory and non-volatile memory of a memory storage device included in the computing system. When the computing system receives a power termination command to remove power, data stored in the volatile memory may be lost, whereas data stored in the non-volatile memory may persist.

### BRIEF DESCRIPTION OF THE DRAWINGS

FIG. 1 illustrates an example diagram of a computing system including an input/output (I/O) controller communicatively coupled to a power management controller (PMC) that is also communicatively coupled to a memory controller and a power control gating consistent with the disclosure.

FIG. 2 illustrates an example diagram of a computing system including a power termination caused by a depress event of a power button for a length of time and an amount of data lost from volatile memory as a result consistent with the disclosure.

FIG. 3 illustrates an example diagram of a computing system implementing a power termination command consistent with the disclosure.

FIG. 4 illustrates an example diagram of a timeline of events in a computing system for implementing a power termination command consistent with the disclosure.

FIG. 5 illustrates an example diagram of a computing system including a PMC communicatively coupled to a first memory storage device and a second memory storage device consistent with the disclosure.

FIG. 6 illustrates an example non-transitory machine-readable medium for implementing a power termination command consistent with the disclosure.

FIG. 7 illustrates an example flow diagram of a method for implementing a power termination command consistent with the disclosure.

### DETAILED DESCRIPTION

Examples described herein relate to a delay of a power termination command of a computing system while data is moved from volatile memory to non-volatile memory of a memory storage device included in the computing system. In examples described herein, the computing system includes a power button, an input/output (I/O) controller, a power management controller (PMC), a power control gating, and the memory storage device. The memory storage device can include a memory controller, a volatile memory (e.g., a dynamic random-access memory (DRAM)-based volatile memory) to cache or buffer the flow of data coming from the computing system, and a non-volatile memory (e.g., a negative-AND (NAND)-based flash non-volatile memory) for more persistent storage of user data, metadata, and other data. Because the memory storage device may include volatile memory and non-volatile memory, the memory storage device may be, as a non-limiting example, a non-volatile memory storage device (e.g., a solid-state drive (SSD)).

In examples described herein, the PMC can be communicatively coupled with the I/O controller, the memory controller, and the power control gating. The I/O controller can be communicative coupled to the PMC through a bus over an interconnected fabric. As an example, the bus can be compliant with an Enhanced Serial Peripheral Interface (eSPI) protocol or other similar protocols of the like. The eSPI protocol allows power management commands, including ones from the I/O controller, to be routed through the PMC. In one example, the I/O controller can detect when a power button of the computing device is depressed. The I/O controller can determine a length of time (e.g., six seconds) for which the power button is being depressed, thereby causing a depress event to occur. As used herein, a depress event includes an engagement or activation of a power button of a computing system (e.g., via physical touch, via remote control, etc.), an unexpected loss of power for a computing system, an unexpected loss of power for a memory storage device, and other similar circumstances of unaccounted for power loss as are known in the art. When the length of time meets at least a threshold period of time (e.g., four seconds), the I/O controller initiates a power termination of the computing system. The I/O controller can accomplish the power termination by transmitting, via the bus, a power termination command to the PMC.

As used herein, the example of six seconds for a length of time of the depress event is non-limiting and the length of time could instead be greater or less than six seconds. As used herein, the example of four seconds for a threshold period of time is non-limiting and the threshold period of time can instead be greater or less than four seconds. As used herein, the term “power termination” describes the removal of power from the computing system sufficient to leave the computing device in a “non-active” mode, such as sleep, hibernate, shut down, power off, etc. For example, power termination could result in the computing system entering a non-active mode of sleep state three (SLP_S3 #). Entrance into the non-active mode can cause data remaining in volatile memory to be lost from the memory storage device included in the computing system.

In response to a receipt of the power termination command, the PMC initiates a preservation of data (e.g., user data and/or metadata) in the volatile memory of the memory storage device. The process involves delaying for a period an assertion of the power termination command to a power control gating. The delay period of the assertion of the power termination command results in adding a configurable amount of time between the assertion and/or de-assertion of other specific commands (e.g., codes sent over communication channels, specific voltage levels applied to specific lines, or other types of commands) by the PMC that are invoked during a power termination of the computing system.

In some examples, prior to, concurrent to, or following the delay of the power termination command, the PMC transmits a memory transfer command to a memory controller included in the memory storage device. The memory transfer command can move data from volatile memory to non-volatile memory of the memory storage device during the delay period. In some examples, the memory transfer command may include a command to cause data from volatile memory to be “flushed” (moved) into non-volatile memory, as is known in the art. In some examples, the command causing the flush may be a reset command for the memory storage device. For example, the command may be a Peripheral Component Interconnect express reset (PERST #) command that causes the data to be flushed from volatile memory into non-volatile memory. For example, the command may be a Power-Loss-Protection (PLP) command to the memory storage device that can also cause the memory storage device to reset and have data flushed from volatile memory to non-volatile memory. Alternatively, or in addition to the example commands stated, the memory transfer command may include a different command to perform a different function that causes the volatile memory to be flushed into non-volatile memory.

In some examples, the delay period may be configurable based on the amount of data to be moved from volatile memory to non-volatile memory, a size of the memory storage device, a rate at which data stored in the memory storage device is utilized, date and/or time when the memory storage device was last used, and/or other characteristics well known in the art. Alternatively, or in addition to the configuration based on the above stated characteristics, the delay period may be set by a manufacturer, an operator, or an end user. As such, as used herein, the examples of how long the delay period will last are non-limiting and can be greater or less than the time listed. Upon expiration of the delay period, the PMC can assert the power termination command to the power control gating.

Alternatively, or in addition to the expiration of the delay period, the memory storage device can transmit a memory transfer confirmation to the PMC when data from the volatile memory has been moved successfully to the non-volatile memory. The memory transfer command can be transmitted in real time, at certain levels of data having been transferred, at certain points in time, upon successful completion, or a combination thereof. When the PMC receives the memory transfer confirmation, the PMC can assert the power termination command to the power control gating, even if the delay period has yet to expire.

For example, a power button of a computing system may be depressed for a length of time (e.g., six seconds). An I/O controller detects the depress of the power button and monitors the length of time. When the length of time at least meets a threshold period of time (e.g., four seconds), the I/O controller transmits a power termination command to a PMC via a bus compliant with an eSPI protocol. The PMC initiates a delay period (e.g., one second) of an assertion of the power termination command to a power control gating and transmit a memory transfer command to a memory controller of a memory storage device included in the computing system. The memory controller can initiate a flush of the volatile memory into non-volatile memory by initiating a reset (e.g., PERST #) process. Upon expiration of the delay period, the PMC can assert the power termination command to the power control gating to remove power from the computing system, including the memory storage device. Alternatively, or in addition, the memory controller can transmit a memory transfer confirmation to the PMC, subsequently causing the PMC to assert the power termination command to the power control gating to remove power from the computing system. The PMC can end the delay period upon receipt of the memory transfer confirmation.

A computing system may include multiple memory storage devices. The PMC can choose from a plurality of ways, or even a combination of different ways from the plurality of ways, to determine a delay period that accounts for data stored in the multiple memory storage devices. The PMC accounting for data stored in the multiple memory storage devices is intended to signify that the PMC is determining a delay period that will allow data stored in volatile memory to be flushed into non-volatile memory of the multiple storage devices. One of the ways the PMC can determine a delay period that accounts for the data is that the PMC can associate a specific delay period with a specific memory storage device of the multiple memory storage devices. When the specific delay period associated with the specific memory storage device of the multiple memory storage devices expires, the PMC can assert the power termination command to the specific memory storage device.

Another way for the PMC to account for the data stored in the multiple memory storage devices is to assert a power termination command for a memory storage device of the multiple memory storage devices when a memory transfer confirmation is received from the specific memory storage device. For example, in a computing system with a first memory storage device and a second memory storage device, the first memory storage device transmits a memory transfer confirmation to the PMC, the PMC asserts a first power termination command to the first memory storage device. The second memory storage device remains free from being affected by the first power termination command asserted to the first memory storage device. When the second memory storage device transmits a memory transfer confirmation to the PMC, the PMC asserts a second power termination command to the second memory storage device. When the PMC receives a memory transfer confirmation, the PMC can end the delay period for the memory storage device the memory transfer confirmation is received from.

Another way for the PMC to account for the data stored in the multiple memory storage devices is by ranking each memory storage device. The ranking can be based on characteristics stated above. In other words, the memory storage devices can be ranked based on a size of the memory storage device, a rate at which data stored in the memory storage device is utilized, date and/or time when the memory storage device was last used, a pre-defined ranking, and/or other characteristics known in the art. In this way, a higher ranked memory storage device can be used for determining the delay period. For example, in a system with a first memory storage device and a second memory storage device, the delay period of the assertion of the power termination command is based on a memory storage device with a higher ranking,

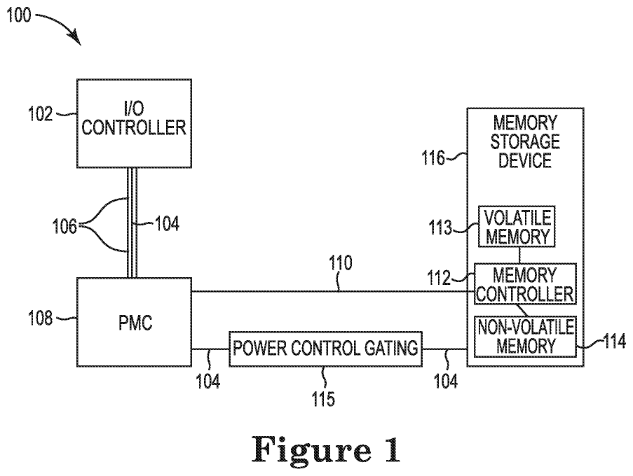

FIG. 1 illustrates an example diagram of a computing system 100 including an I/O controller 102 communicatively coupled to a PMC 108 that is also communicatively coupled to a memory controller 112 and a power control gating 115. As used herein, a computing system 100 includes a computing device connected to a memory resource, a processing resource, and a variety of peripheral devices (e.g., keyboard, mouse, solid-state drive, etc.). As used herein, an I/O controller 102 is a hardware component included in the computing system 100 that used to manage communications between the peripheral devices and the computing system. As used herein, a PMC 108 is a hardware component that manages power functions of the computing system 100. As used herein, a memory controller 112 is a hardware component that manages data stored in the memory storage device 116. As used herein, a power control gating 115 is a hardware component that allows the computing system 100 to be in different modes of power, such as an active mode or a non-active mode. As used herein, a memory storage device 116 is a device that stores data for use by the computing system 100, wherein the data can be stored in a volatile memory 113 and/or a non-volatile memory 114. An example of a memory storage device is a non-volatile storage device, such as a solid-state drive.

As shown in FIG. 1, the I/O controller 102 transmits a power termination command 104, via a bus 106 over an interconnected fabric, to the PMC 108. The bus 106 can be compliant with an enhanced Serial Interface Protocol (eSPI) protocol, which allows the I/O controller to provide multiple commands, including the power termination command 104, to the PMC 108 via the bus 106. In addition, a command transferred via the bus 106 can receive priority over any other command; the PMC 108 is to gate other commands as it addresses the power termination command 104 sent to the PMC 108 by the I/O controller 102. The power management controller 108, and the computing system 100 overall, can be updated for utilization of the bus 106 independent of a physical component configuration.

The PMC 108 can address the power termination command 104 by initiating a delay period of an assertion of the power termination command 104 to a power control gating 115. The delay period may extend for a predetermined but configurable amount of time. The delay period may last for one second but can last for more or less than one second based on the configuration. During the delay period, the PMC 108 is to transmit a memory transfer command 110 to a memory controller 112 included within a memory storage device 116. The memory storage device is to include the memory controller 112, a volatile memory 113, and a non-volatile memory 114. As an example, the memory transfer command 110 from the PMC 108 is to cause the memory controller 112 to initiate a flush for the memory storage device 116, and thereby cause data from the volatile memory to be flushed into the non-volatile memory. In some examples, reset proceedings can initiate a flush that may comprise a Peripheral Component Interface express (PCIe) being reset (PERST #) so as to have data in volatile memory to be moved to non-volatile memory. Alternatively, the memory controller 112 could initiate other functions that cause data from the volatile memory to be flushed into the non-volatile memory. In other words, the memory transfer command 110 comprises instructions to move data from the volatile memory to the non-volatile memory.

Upon expiration of the delay period, the PMC 108 is to assert the power termination command 104 to the power control gating 115, which in turn is to remove power from the computing system 100, including the memory storage device 116. Removal of power is to reach a level where volatile memory from the memory storage device 116 is to be lost. As such, the state the computing system 100 may be powered down to ranges from such things as a sleep state three (SLP_S3 #) to a complete loss of power.

Alternative to, or in addition to, the expiration of the delay period, the memory controller 112, or the memory storage device 116, may transmit a memory transfer confirmation to the PMC 108 when an amount of data stored in the volatile memory has been transferred to the non-volatile memory. The amount of data may be a complete amount of the data stored in the volatile memory or a lesser amount; the amount to be moved may be predetermined by a manufacturer, but configurable by an operator, an end user, etc. As such, when the PMC 108 receives the memory transfer confirmation from the memory controller 112, or the memory storage device 116, the PMC 108 asserts the power termination command 104 to the power control gating 115 independent of the expiration of the delay period. As used herein, “independent of the expiration of the delay period” describes assertion of the power termination command by the PMC based on a receipt of the memory transfer confirmation even when the delay period has yet to expire,

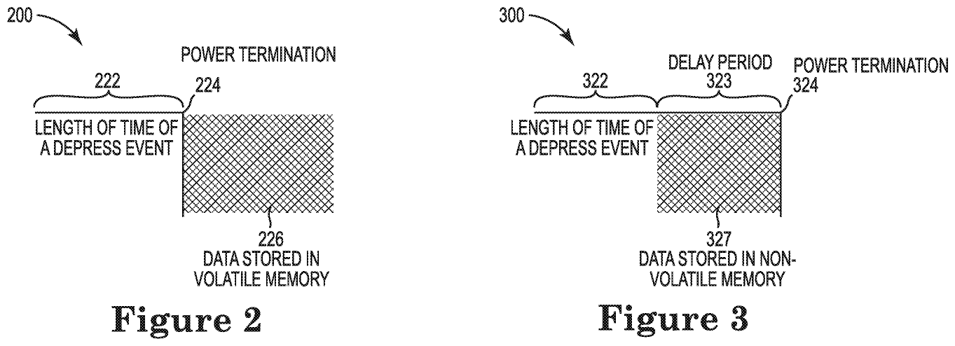

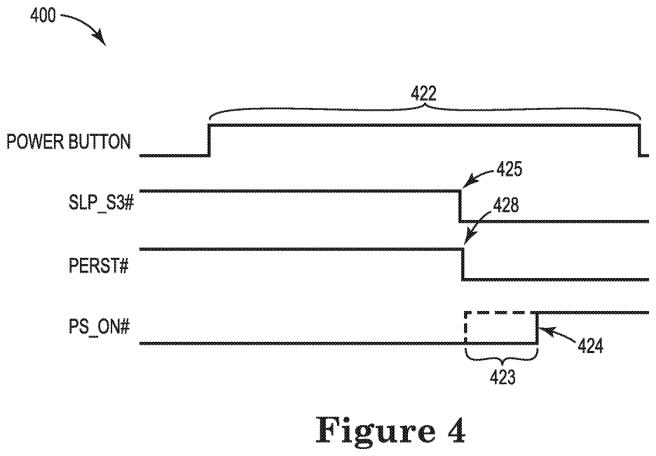

FIG. 2 illustrates an example diagram of a computing system 200 including a power termination 224 caused by a depress event of a power button for a length of time 222 and an amount of data 226 lost from volatile memory as a result consistent with the disclosure. The computing system 200 experiences the power termination 224 when the power button (not shown) undergoes a depress event (is depressed) for a length of time 222 (e.g., six seconds). As has been described, an I/O controller (shown as 102 in FIG. 1) monitors the depress event of the power button and the I/O controller determines the length of time 222 the power button is depressed for. When the length of time 222 meets a threshold period of time (shown as 425 in FIG. 4), the I/O controller initiates a power termination 224 of the computing system 200. As such, the I/O controller sends a power termination command (shown as 104 in FIG. 1) to a power management controller (PMC) (shown as 108 in FIG. 1) via a bus compliant with eSPI (shown as 106 in FIG. 1), The PMC, upon receiving the power termination command, asserts the power termination command to a power control gating (shown as 115 in FIG. 1) without any delay. As such, for example, an active low command (PS_ON #) of the computing device 200 is de-asserted, and, as described above for example, a sleep state three (SLP_53 #) command is asserted. In this example, the SLP_S3 # command signifies entrance into a non-active mode where data 226 stored in volatile memory is lost.

This is to be considered an “unclean” shut down as it does not allow the computing system 200 to move data 226 stored in volatile memory to non-volatile memory, and therefore ends up in losing said data 226 instead of saving it for when the computing system 200 is made active again. The computing system 200, for example, may be made active again when the computing system 200 wakes from hibernation or starts again from a shut down. FIG. 2 is intended to serve as an example of how computing systems currently respond to their power buttons being depressed for the length of time.

FIG. 3 illustrates an example diagram of a computing system 300 implementing a power termination command consistent with the disclosure. The computing system 300 includes a power termination 324 caused by a depress event of a power button for a length of time 322, a delay period 323 of the power termination, and an amount of data 327 transferred to non-volatile memory (shown as 114 in FIG. 1) as a result of the delay period 323. FIG. 3 is similar to FIG. 2 in that the computing system 300 undergoes the power termination 324 after the power button of computing system 300 is depressed for the length of time 322 (e.g., six seconds), A difference between FIGS. 2 and 3 is that in FIG. 3, a delay period 323 takes place that allows for data stored in volatile memory (shown as 113 in FIG. 1) to be moved and become data 327 stored in the non-volatile memory.

As has been described, an I/O controller (shown as 102 in FIG. 1) monitors the depress event of the power button and the I/O controller determines the length of time 322 the power button is depressed for. When the length of time 322 meets a threshold period of time (shown as 425 in FIG. 4), the I/O controller initiates a power termination 324 of the computing system 300 and sends a power termination command (shown as 104 in FIG. 1) to a power management controller (PMC) (shown as 108 in FIG. 1). The PMC initiates a delay period 323 of assertion of the power termination command. During this delay period, the PMC transmits a memory transfer command (shown as 110 in FIG. 1) to a memory controller (shown as 112 in FIG. 1) included in a memory storage device (shown as 116 in FIG. 1). Upon expiration of the delay period 323, or, alternatively or in addition, when the PMC receives a memory transfer confirmation signifying that data has been moved from volatile memory to non-volatile memory, the PMC asserts the power termination command to a power control gating (shown as 115 in FIG. 1). The power control gating subsequently transmits the power termination to the memory storage device, causing it to power down as well as the computing system 300 as a whole.

The power removal from the computing system 300 in FIG. 3 is distinct from the power removal from the computing system 200 in FIG. 2 because the data stored in the volatile memory is moved to the non-volatile memory in FIG. 3, whereas the data stored in the volatile memory is lost in FIG. 2.

FIG. 4 illustrates an example diagram of a timeline of events in a computing system 400 for implementing a power termination command consistent with the disclosure. The computing system 400 includes a length of time 422 of a power button being depressed, a threshold period of time 425 after which a sleep state three (SLP_S3 #) command is transmitted, a delay period 423 before the SLP_S3 # command is asserted, a point in time 428 when a PERST # command is transmitted, and a power termination 424 upon assertion of the SLP_S3 # command. As stated above, the PERST # command is being used as a non-limiting example and can instead be replaced by another command that causes data to be flushed from volatile memory to non-volatile memory.

In the non-limiting example of FIG. 4, the power button (not shown) of the computing system 400 is depressed for the length of time 422 (e.g., 6 seconds), This depression of the power button is detected and monitored by an I/O controller (shown as 102 in FIG. 1). The depression of the power button can also be detected and tracked by a power management controller (PMC) (shown as 108 in FIG. 1). When the threshold period of time 425 is met by the length of time 422 of the power button being depressed (depress event), the I/O controller transmits, via a bus compliant with an Enhanced Serial Peripheral Interface (eSPI) protocol, a power termination command (shown as 104 in FIG. 1) to the PMC.

In the non-limiting example of FIG. 4, the power termination command is a command to enter a non-active mode of sleep state three (SLP_S3 #). When the computing system 400 enters the non-active mode of SLP_S3 #, an unclean shut down occurs and data (shown as 226 in FIG. 2) stored in volatile memory is lost. To avoid the unclean shut down, the PMC initiates a delay period 423 of the assertion of the SLP_S3 # (power termination) command and transmits a memory transfer command to a memory controller (shown as 112 in FIG. 1). The memory transfer command is labelled PERST # because it signifies a reset of the Peripheral Component Interface express (PERST #) bus, which causes data to be moved from volatile memory to non-volatile memory in a memory storage device (shown as 116 in FIG. 1) included in the computing system 400. As such, data is saved (shown as 327 in FIG. 3) due to the delay of the entrance into the non-active mode (SLP_S3 #).

In the example of FIG. 4, the power termination 424 is on a command known as an active low command (PS_ON #). When PS_ON # is de-asserted, power termination occurs. As such, when the delay period 423 expires, the PMC asserts the power termination command of SLP_S3 #, PS_ON # is de-asserted, and the computing system 400 has power termination 424 occur.

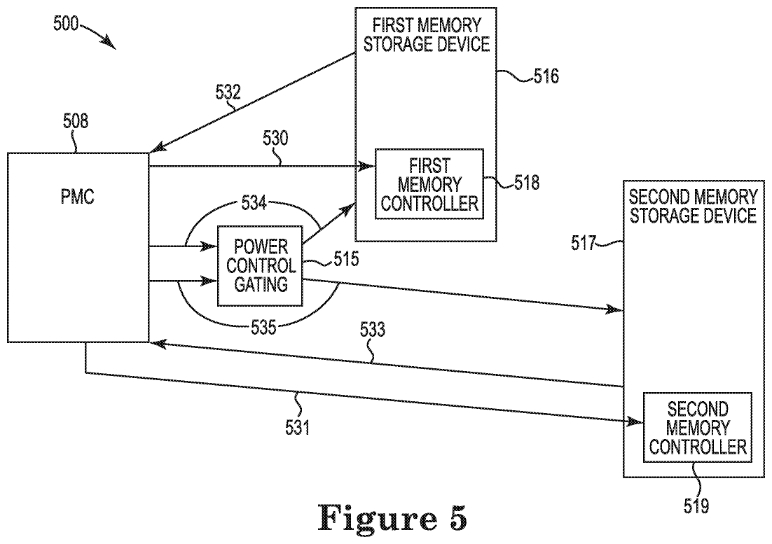

FIG. 5 illustrates an example diagram of a computing system 500 including a PMC 508 communicatively coupled to a first memory storage device 516 and a second memory storage device 517 consistent with the disclosure. In FIG. 5, the PMC 508 receives a power termination command (shown as 104 in FIG. 1) from an I/O controller (shown as 102 in FIG. 1) via a bus over an interconnected fabric (shown as 106 in FIG. 1). Furthermore, the bus is compliant with an eSPI protocol.

In response to receiving the power termination command, the PMC 508 can transmit a first memory transfer command 530 to a first memory controller 518 of the first memory storage device 516 and a second memory transfer command 531 to a second memory controller 519 of the second memory storage device 517. After transmitting the memory transfer commands 530 and 531, the PMC 508 can initiate a delay period (shown as 323 in FIGS. 3 and 423 in FIG. 4) that accounts for data stored in volatile memory (shown as 113 in FIG. 1) of each memory storage device to be moved to non-volatile memory (shown as 114 in FIG. 1) of each memory storage device. Alternatively, the PMC 508 can initiate the delay period in response to receiving the power termination command followed by transmitting the memory transfer commands 530 and 531. Alternatively, the PMC 508 can concurrently initiate the delay period and transmit the memory transfer commands 530 and 531 in response to receiving the power termination command.

As listed above, the PMC 508 can determine the delay period in a plurality of ways. One of the ways the PMC 508 can determine a delay period that accounts for the data stored in the volatile memory of each memory storage device is that the PMC 508 can assert the power termination command for a specific memory storage device of the multiple memory storage devices when a memory transfer confirmation is received from the specific memory storage device. For example, as illustrated in FIG. 5, the PMC 508 can initiate separate delay periods for the first memory storage device 516 and the second memory storage device 517. When the first memory storage device 516 transmits a memory transfer confirmation 532 to the PMC 508, the PMC 508 can assert a first power termination command 534 to the first memory storage device 516 through a power control gating 515. When the second memory storage device 517 transmits a memory transfer confirmation 533 to the PMC 508, the PMC 508 can assert a second power termination command 535 to the second memory storage device 517 through the power control gating 515. The first memory storage device 516 is to be free of affect from the second power termination command 535 and the second memory storage device 517 is to be free of affect from the first power termination command 534.

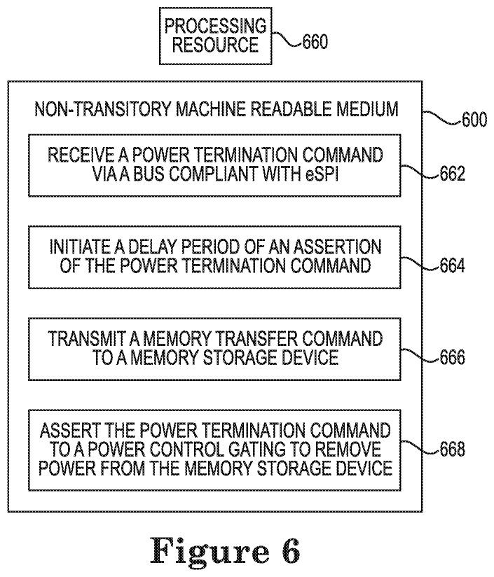

FIG. 6 illustrates an example non-transitory machine-readable medium 600 for implementing a power termination command consistent with the disclosure. A processing resource 660 may execute instructions stored on the non-transitory machine readable medium 600. The processing resource 660 may be a hardware processing unit such as a microprocessor, application specific instruction set processor, coprocessor, network processor, or similar hardware circuitry that can cause machine-readable instructions to be executed. In some examples, the processing resource 660 may be a plurality of hardware processing units that can cause machine-readable instructions to be executed. The processing resource 660 can include central processing units (CPUs) and/or graphics processing units (GPUs), among other types of processing units. The non-transitory machine readable medium 600 may be any type of volatile or non-volatile memory or storage, such as random-access memory (RAM), flash memory, read-only memory (ROM), storage volumes, a hard disk, or a combination thereof.

The example medium 600 stores instructions 662 executable by the processing resource 660 to receive a power termination command (shown as 104 in FIG. 1) from an I/O controller (shown as 102 in FIG. 1) via a bus (shown as 106 in FIG. 1) compliant with an eSPI protocol. The example medium 600 stores instructions 664 executable by the processing resource 660 to initiate a delay period of an assertion of the power termination command. The example medium 600 stores instructions 666 executable by the processing resource 660 to transmit a memory transfer command (shown as 110 in FIG. 1) to a memory storage device (shown as 116 in FIG. 1). The example medium 600 stores instructions 668 executable by the processing resource 660 to assert the power termination command to a power control gating (shown as 115 in FIG. 1) upon expiration of the delay period to remove power from the memory storage device.

The example medium 600 can also store instructions executable by the processing resource 660 to receive a memory transfer confirmation from the memory storage device. The example medium 600 can also store instructions executable by the processing resource 660 to assert the power termination command to the power control gating to remove power from the memory storage device when the memory transfer confirmation is received, even when the delay period has yet to expire.

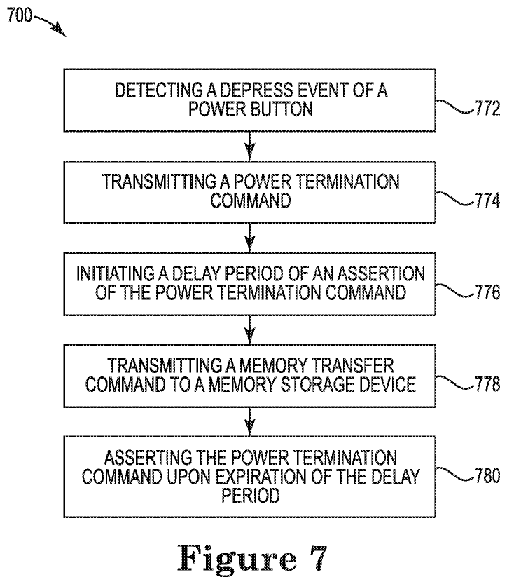

FIG. 7 illustrates an example flow diagram of a method 700 for implementing a power termination command consistent with the disclosure. At block 772, the method 700 can include detecting a depress event of a power button. For example, the method 700 can include an I/O controller (shown as 102 in FIG. 1) detecting a depress event of a power button of a computing system (shown as 100 in FIG. 1). For example, the method 700 can include a PMC (shown as 108 in FIG. 1) detecting a depress event of a power button of a computing system (shown as 100 in FIG. 1). In some examples, the depress event can continue for a length of time (e.g., six seconds).

At block 774, the method 700 can include transmitting a power termination command to the PMC, For example, the method can include the I/O controller transmitting a power termination command to the PMC. At block 776, the method 700 can include initiating a delay period of an assertion of the power termination command. For example, the method 700 can include the PMC initiating a delay of the assertion to a power control gating (shown as 115 in FIG. 1) of the power termination command.

At block 778, the method 700 can include transmitting a memory transfer command (shown as 110 in FIG. 1) to a memory storage device (shown as 116 in FIG. 1). In some examples, the method 700 can include the PMC transmitting a memory transfer command to a memory controller (shown as 112 in FIG. 1) of the memory storage device. In some examples, the method 700 can include the PMC transmitting the memory transfer to the memory storage device.

At block 780, the method 700 can include asserting the power termination command upon expiration of the delay period. For example, the method can include the PMC asserting the power termination command to the power control gating to remove power. In some examples, the power termination command can include removing power from the memory storage device. In some examples, the power termination command can include removing power from the computing system.

In some examples, the detecting can comprise monitoring, by the I/O controller, the length of time for which the power button is depressed. In other examples or in addition, the detecting can further comprise determining, by the I/O controller, when the length of time at least meets a threshold period of time that initiates a power termination of the computing device.

In some examples, the power termination command can cause the memory storage device to enter a non-active mode where volatile memory is lost. In other examples or in addition, the power termination command can cause the computing device to power off.

In some examples, the memory transfer command can include a command for the memory storage device to reset.

In some examples, the method 660 can further comprise asserting, by the PMC, the power termination command to the power control gating independent of the expiration of the delay period when the PMC receives a memory transfer confirmation from the memory storage device.

In some examples, the memory storage device can be a solid-state drive, or another non-volatile storage device of the sort.

In the examples above, a time that components take to process and transmit commands was ignored to show the concept in a clear fashion. Described above and throughout this disclosure are examples that are not intended to be limiting. Components described herein may be combined or made further separate. Terms used herein, such as “sleep state three”, are well known to individuals skilled in the art.

What is claimed:

1. A system comprising:
a memory storage device including:
a memory controller,
non-volatile memory; and
volatile memory;
an input/output (I/O) controller coupled to the memory storage device; and
a power management controller (PMC) coupled to the I/O controller to:
receive, via a bus over an interconnected fabric, a power termination command from the I/O controller to the power management controller;
initiate a delay period of an assertion of the power termination command;
during the delay period, transmit a memory transfer command to the memory controller responsive to a receipt of the power termination command, wherein the memory transfer command comprises instructions to move data from the volatile memory to the non-volatile memory; and
assert, upon an expiration of the delay period, the power termination command to a power control gating to remove power.

2. The system of claim 1, wherein the bus is compliant with an enhanced Serial Peripheral Interface (eSPI) protocol, wherein I/O controller is to provide multiple commands including the power termination command to the power management controller via the bus.

3. The system of claim 1, wherein a command transferred via the bus is to receive priority over any other command.

4. The system of claim 1, wherein the PMC is to be updated for utilization of the bus independent of a physical component configuration.

5. The system of claim 1, wherein the delay period of the assertion of the power termination command is to extend for an amount of time.

6. A method, comprising:
detecting, by an input/output (I/O) controller of a computing device, a depress of a power button of the computing device;
transmitting, by the I/O controller via a bus compliant with an Enhanced Serial Peripheral Interface (eSPI) protocol, a power termination command to a power management controller (PMC) of the computing device;
initiating, by the PMC, a delay period of an assertion of the power termination command;
transmitting, by the PMC to a memory controller of a memory storage device of the computing device, a memory transfer command responsive to the initiation of the delay period of the assertion of the power termination command, wherein the memory transfer command comprises instructions to move data from volatile memory to non-volatile memory of the memory storage device; and
asserting, by the PMC upon an expiration of the delay period, the power termination command to remove power to a power control gating of the memory storage device.

7. The method of claim 6, wherein the detecting comprises:
monitoring, by the I/O controller, a length of time for which the power button is depressed; and
determining; by the I/O controller; when the length of time at least meets a threshold period of time that initiates a power termination of the computing device.

8. The method of claim 6, wherein the power termination command causes the memory storage device to enter a non-active mode where volatile memory is lost.

9. The method of claim 6, wherein the power termination command causes the computing device to power off.

10. The method of claim 6, wherein the memory transfer command includes a command for the memory storage device to reset.

11. The method of claim 6, further comprising asserting, by the PMC, the power termination command to the power control gating independent of the expiration of the delay period when the PMC receives a memory transfer confirmation from the memory storage device.

12. The method of claim 6, wherein the memory storage device is a solid-state drive.

13. A computing system comprising:
a power management controller (PMC);
an input/output (I/O) controller to:
detect a depress event of a power button of the computing system; and
transmit, to the PMC via a bus compliant with an Enhanced Serial Peripheral Interface (eSPI) protocol, a power termination command, wherein the depress event is detected for a threshold period of time;
the PMC to:
initiate a delay period of an assertion of the power termination command;
responsive to a receipt of the power termination command, transmit a memory transfer command to a first non-volatile storage device and a second non-volatile storage device, wherein the memory transfer command comprises instructions to move data from volatile memory of the first and second non-volatile storage devices to non-volatile memory of the first and second non-volatile storage devices, respectively;
receive a first memory transfer confirmation from the first non-volatile storage device and a second memory transfer confirmation from the second non-volatile storage device; and
responsive to a receipt of the first and second memory transfer confirmations, assert the power termination command to a power control gating to remove power from the computing system, including the first and second non-volatile storage devices.

14. The computing system of claim 13, wherein the delay period extends until the first non-volatile storage device has transmitted the first memory transfer confirmation to the PMC, and the second non-volatile storage device has transmitted the second memory transfer confirmation to the PMC.

15. The computing system of claim 13, wherein, independent of the receipt of the first and second memory transfer confirmations, the PMC is to assert, upon an expiration of the delay period, the power termination command to the power control gating to remove power from the computing system, including the first and second non-volatile storage devices.
